(19) United States
(12) Patent Application Publication
(10) Pub. No.: US 2025/0171898 A1
(43) Pub. Date: May 29, 2025

(54) HEATER ASSEMBLY INCLUDING COOLING APPARATUS AND METHOD OF USING SAME

(71) Applicant: ASM IP Holding B.V., Almere (NL)

(72) Inventors: Carl Louis White, Gilbert, AZ (US); Eric James Shero, Phoenix, AZ (US); Kyle Fondurulia, Phoenix, AZ (US); Timothy James Sullivan, Gilbert, AZ (US)

(21) Appl. No.: 19/027,188

(22) Filed: Jan. 17, 2025

Related U.S. Application Data
(62) Division of application No. 16/983,364, filed on Aug. 3, 2020, now Pat. No. 12,247,286.
(60) Provisional application No. 62/885,149, filed on Aug. 9, 2019.

(51) Int. Cl. C23C 16/455; C23C 16/52

(52) U.S. Cl. CPC C23C 16/45544; C23C 16/45561; C23C 16/52

(57) ABSTRACT

A cooling apparatus and methods for maintaining a precursor source vessel heater at a desired temperature are disclosed. The apparatus and methods can be used to maintain a desired temperature gradient within the precursor source vessel for improved integrity of the precursor source before delivery of the precursor to a reaction chamber. The apparatus and methods can also be used for rapid cooling of a source vessel for maintenance.

### CROSS-REFERENCE TO RELATED APPLICATIONS

This application is a divisional of, and claims priority to and the benefit of, U.S. patent application Ser. No. 16/983,364, filed Aug. 3, 2020 and entitled “HEATER ASSEMBLY INCLUDING COOLING APPARATUS AND METHOD OF USING SAME,” which is a nonprovisional of, and claims priority to and the benefit of, U.S. Provisional Patent Application No. 62/885,149, filed Aug. 9, 2019 and entitled “HEATER ASSEMBLY INCLUDING COOLING APPARATUS AND METHOD OF USING SAME,” which are hereby incorporated by reference herein.

### FIELD OF INVENTION

The present disclosure generally relates to an apparatus for cooling a heater for a precursor source vessel in a reactor system and methods of its use.

### BACKGROUND OF THE DISCLOSURE

Gas-phase reactor systems can include solid or liquid precursor source delivery systems to deliver gas-phase reactants to a reaction chamber. A typical solid or liquid precursor source delivery system includes a solid or liquid precursor source vessel and a heating means. The heating means may include one or more heaters for heating the interior of the vessel to a desired operating temperature.

During operation, in order to maintain a steady state temperature, and prevent overheating of the vessel, the heating means typically cycles off for periods of time. This duty cycle, and particularly the turning off of the heating means, may compromise the temperature control within the vessel, which, in turn, may compromise the integrity of the precursor source material. Accordingly, improved apparatuses for controlling a temperature of the vessel are desired.

A solid precursor source vessel is typically operated at high temperatures, e.g., about 110-210° C. Therefore, the vessel may be desirably cooled to a safe temperature for maintenance activities, such as cleaning and chemical refill of the vessel. With typical solid or liquid precursor source delivery systems, a cooling time can be undesirably long. Accordingly, improved apparatuses for more rapidly cooling the precursor source delivery systems are desired.

Any discussion of problems and solutions set forth in this section has been included in this disclosure solely for the purpose of providing a context for the present disclosure, and should not be taken as an admission that any or all of the discussion was known at the time the invention was made.

### SUMMARY OF THE DISCLOSURE

Exemplary embodiments of this disclosure provide methods and an apparatus for cooling a precursor source vessel suitable for use with or in a reactor system. While the ways in which various embodiments of the present disclosure address drawbacks of prior methods and systems are discussed in more detail below, in general, various embodiments of the disclosure provide apparatus and methods that can be used to cool a precursor source vessel and components thereof (e.g., a heater), as well as reduce the temperature of a precursor source vessel for quicker access for maintenance of the precursor source vessel and/or a reactor system including the precursor source vessel.

In various embodiments of the disclosure, an assembly comprises a precursor source vessel; a heating element in thermal communication with the precursor source vessel; and a cooling apparatus in thermal contact with the heating element, wherein the heating element heats an interior of the precursor source vessel, and wherein the cooling apparatus removes heat from the heating element.

The heating element can comprise a heating plate in contact with the precursor source vessel. The heating plate can be in thermal contact with a cooling apparatus, which can be a cooling plate.

The cooling plate may be comprised of one or more of aluminum, stainless steel, nickel, and hastelloy. The cooling plate comprises a top side and a bottom side. The top side can contact the heating plate. The bottom side can be in thermal contact with, cooling elements, such as one or more cooling lines, configured to hold a fluid. The fluid can be, for example, air, water, chilled water, or ethylene glycol. The one or more cooling lines may be attached to or embedded within the bottom side of the cooling plate. The one or more cooling lines may be comprised of stainless steel, aluminum, nickel, or hastelloy. The cooling lines can further comprise a valve configured to control a flow rate of a fluid through the one or more cooling lines, which in turn control the cooling function of the cooling plate. The cooling lines can comprise a serpentine path that is concentrated (e.g., has a greater number of segments) proximate a center portion of the cooling plate.

The assembly may further comprise a control system configured to control one or more of a flow rate of the fluid and a temperature of the fluid. The control system can communicate with one or more sensors configured to detect a running temperature of one or more of the heating element, the cooling apparatus, and the vessel.

In various embodiments of the disclosure, a method of controlling the temperature of an interior of a precursor source vessel comprises heating the precursor source vessel using a heating element and cooling the heating element using a cooling apparatus. The interior may be heated to a desired temperature, e.g., greater than the sublimation temperature of a precursor and less than the decomposition temperature of the precursor. The temperature can range between, for example, 90° C. to 250° C., or 110° C. to 210° C. The heating element can continually provide heat to maintain the desired temperature, i.e. power can be continually supplied to the heating element (e.g. via a controller) for a period of time, such as during one or more substrate processes within a reaction chamber. A temperature of the heating element and/or cooling apparatus may be manipulated to form a temperature gradient within the interior from a first temperature at a bottom end of the precursor source vessel to a second temperature near a top end of the precursor source vessel, wherein the first temperature is less than the second temperature. For other applications, the heating element can be turned off, allowing the cooling apparatus to draw residual heat from the heating element, thereby rapidly reducing the temperature of the interior of the precursor source vessel.

A pressure within the precursor source vessel of the present disclosure can be between about a vacuum pressure and 760 Torr, between about 5 and 50 Torr, between about 3 and 350 Torr, between about 50 and 250 Torr, or between about 100 and 2000 Torr.

In various embodiments of the disclosure, a reactor system comprises an assembly comprising a precursor source vessel; a heating element in thermal communication with the precursor source vessel; and a cooling apparatus in thermal contact with the heating element, wherein the heating element heats an interior of the precursor source vessel, and wherein the cooling apparatus removes heat from the heating element. A temperature gradient can be formed within the interior from a first temperature at a bottom end of the precursor source vessel and a second temperature near the top end of the precursor source vessel, where the first temperature can be less than the second temperature.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

A more complete understanding of exemplary embodiments of the present disclosure can be derived by referring to the detailed description and claims when considered in connection with the following illustrative figures.

FIG. 1 illustrates a top view of a cooling apparatus in accordance with an embodiment of the disclosure.

FIG. 2 illustrates a bottom view of the cooling apparatus of FIG. 1 in accordance with an embodiment of the disclosure.

FIG. 3 illustrates a top view of a cooling apparatus with a heating element in accordance with at least one embodiment of the disclosure.

FIG. 4 illustrates a bottom view of the cooling apparatus and heating element of FIG. 3 in accordance with an embodiment of the disclosure.

FIG. 5 illustrates a schematic of a solid precursor source vessel, heating element, and cooling apparatus in accordance with an embodiment of the disclosure.

FIG. 6 illustrates an exemplary source vessel for use with the cooling apparatus in accordance with an embodiment of the disclosure.

FIG. 7 illustrates a schematic of a reactor system comprising a reaction chamber with a solid precursor source vessel, heating element, and cooling apparatus in accordance with a embodiment of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to cooling methods and apparatus for use with a precursor source vessel, and assemblies and reactor systems that include such apparatus and vessels. As described in more detail below, exemplary methods can be used to maintain a heating element at a desired temperature, and to facilitate rapid cooling of a vessel for accessibility during maintenance. In addition, the reactor systems, assemblies, and vessels can be used to generate a desired temperature profile within the vessel to provide a precursor to a reaction chamber.

Exemplary precursor source vessels, assemblies, reactor systems, and methods discussed herein can be used for a variety of applications. For example, the vessels, assemblies, and reactor systems can be used for chemical vapor deposition (CVD) and/or atomic layer deposition (ALD) processes.

CVD includes forming thin film of materials on substrates using reactant vapors (including “precursor gases”) of different reactant chemicals that are delivered to one or more substrates in a reaction chamber. In many cases, the reaction chamber includes only a single substrate supported on a substrate holder (such as a susceptor), with the substrate and substrate holder being maintained at a desired process temperature. In typical CVD processes, reactive reactant vapors react with one another to form thin films on the substrate, with the growth rate being related to the temperature and the amounts of reactant gases. In some cases, energy to drive the deposition process is supplied in part by plasma, e.g., by a remote or direct plasma process.

In some applications, the reactant gases are stored in gaseous form in a reactant source vessel. In such applications, the reactants are often gaseous at standard pressures and temperatures of around 1 atmosphere and room temperature. Examples of such gases include nitrogen, oxygen, hydrogen, and ammonia. However, in some cases, the vapors of source chemicals or precursors that are liquid or solid (e.g. hafnium chloride, hafnium oxide, zirconium dioxide, or the like) at standard pressure and temperature are used. For some solid substances (referred to herein as “solid source precursors”), the vapor pressure at room temperature is so low that the substances are typically heated and/or maintained at very low pressures to produce a sufficient amount of reactant vapor for the reaction process. Once vaporized, it is important that the vapor phase reactant is kept at or above the vaporizing temperature through the processing system so as to prevent undesirable condensation in the valves, filters, conduits, and other components associated while delivering the vapor phase reactants to the reaction chamber. Vapor phase reactants from such naturally solid or liquid substances may be useful for chemical reactions in a variety of applications.

ALD is another process for forming thin films on substrates. In many applications, ALD uses a solid and/or liquid source chemical as described above. ALD is a type of vapor deposition wherein a film is built up through, e.g., self-saturating reactions performed in cycles. A thickness of an ALD-deposited film can be determined by the number of ALD cycles performed. In an ALD process, gaseous reactants are supplied, alternatingly and/or repeatedly, to the substrate to form a thin film of material on the substrate. One reactant absorbs in a self-limiting process on the substrate. A different, subsequently pulsed reactant reacts with the adsorbed material to form a single molecular layer of the desired material. Decomposition may occur through mutual reaction between the adsorbed species and with an appropriately selected reactant, such as in a ligand exchange or a gettering reaction. In a theoretical ALD reaction, no more than a molecular monolayer forms per cycle. Thicker films are produced through repeated growth cycles until the target thickness is achieved.

In theoretical ALD reactions, mutually reactive reactants are kept separate in the vapor phase with intervening removal processes between substrate exposures to the different reactants. For example, in time-divided ALD processes, reactants are provided in pulses to a stationary substrate, typically separated by purging or pump down phases; in space-divided ALD processes, a substrate is moved through zones with different reactants; and in some processes, aspects of both space-divided and time-divided ALD can be combined. Variants or hybrid processes of ALD and CVD allow some amount of CVD-like reactions, either through selection of the deposition conditions outside the normal ALD parameter windows and/or through allowing some amount of overlap between mutually reactive reactants during exposure to the substrate.

In this disclosure, an assembly may include a solid or liquid precursor source vessel, a heating element, and a cooling apparatus. The heating element is in thermal communication with the source vessel, and the cooling apparatus is in thermal contact with the heating element.

The cooling apparatus can be cooled, in order to cool a surrounding environment. In some embodiments, the cooling apparatus comprises a cooling plate. In some embodiments, the cooling plate is the same shape or a similar shape as the heating element. For example, the cooling plate can be rectangular, circular, hexagonal octagonal, or any other shape.

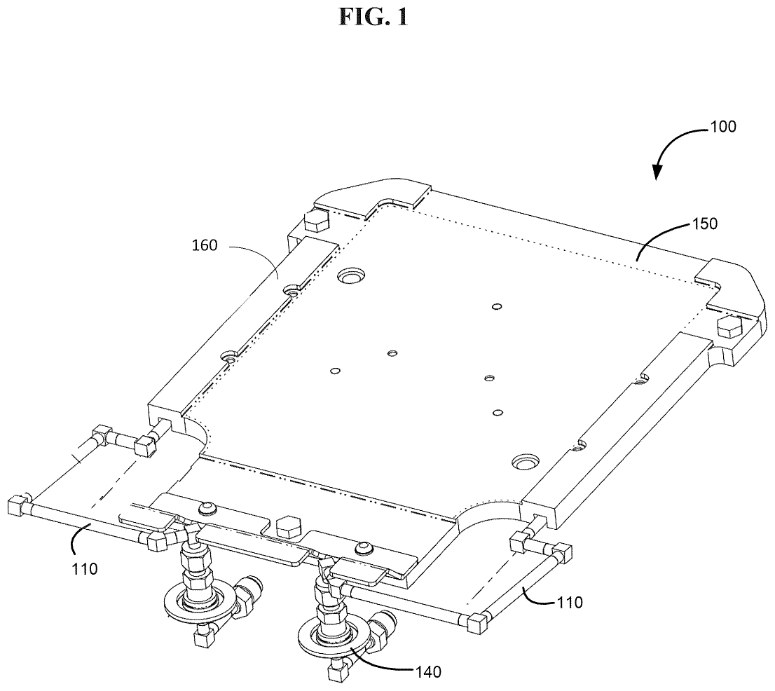

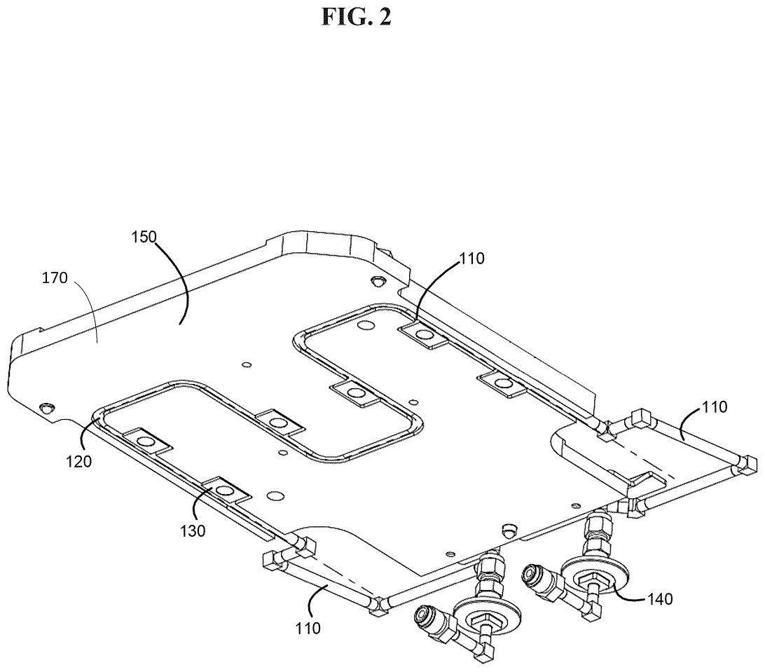

FIGS. 1 and 2 illustrate a cooling apparatus 100 according to some embodiments. The cooling apparatus 100 comprises a cooling plate 150. Cooling apparatus 100 has a top side 160, as depicted in FIG. 1, which thermally contacts the heating element. A bottom side 170 of cooling apparatus 100, as depicted in FIG. 2 can include or be in thermal contact with one or more cooling lines 110, which define a fluid path that runs across a portion of the bottom side 170 of cooling apparatus 100. In some embodiments, the bottom side 170 of cooling apparatus 100 includes one or more recesses 120 for receiving cooling lines 110. In some embodiments, cooling lines 110 run through the cooling plate 150 in a serpentine fluid path, where the fluid can run vertically and/or horizontally proximate a center portion of cooling apparatus 100 several times, as illustrated in FIG. 2. Other fluid paths may be used (e.g. a zig-zag fluid path, a wave fluid path, etc.). In some embodiments, cooling lines 110 are secured to cooling plate 150 by clamps 130. Other mechanical attachments may be used (e.g. bolts, screws, etc.).

In some embodiments, cooling lines 110 are configured to receive fluid from a fluid source. In some embodiments, the fluid enters cooling lines 110 through valves 140. In some embodiments, the fluid is water. In some embodiments, the fluid is chilled water. In some embodiments, the fluid is air. In some embodiments, the fluid is ethylene glycol. The fluid can be maintained at a temperature that can cool cooling apparatus 100 to a temperature that draws thermal energy from heating element 200. As thermal energy is (e.g., continuously) dissipated away from heating element 200, heating element 200 can maintain a desired, e.g., steady, temperature without having to stop emitting heat. In some embodiments, cooling element 100 maintains heating element 200 at temperature that does not increase or decrease more than 5° C., 3° C., or 1.5° C., during the operation of reactor systems, assemblies, and vessels, e.g. during a CVD and/or ALD process.

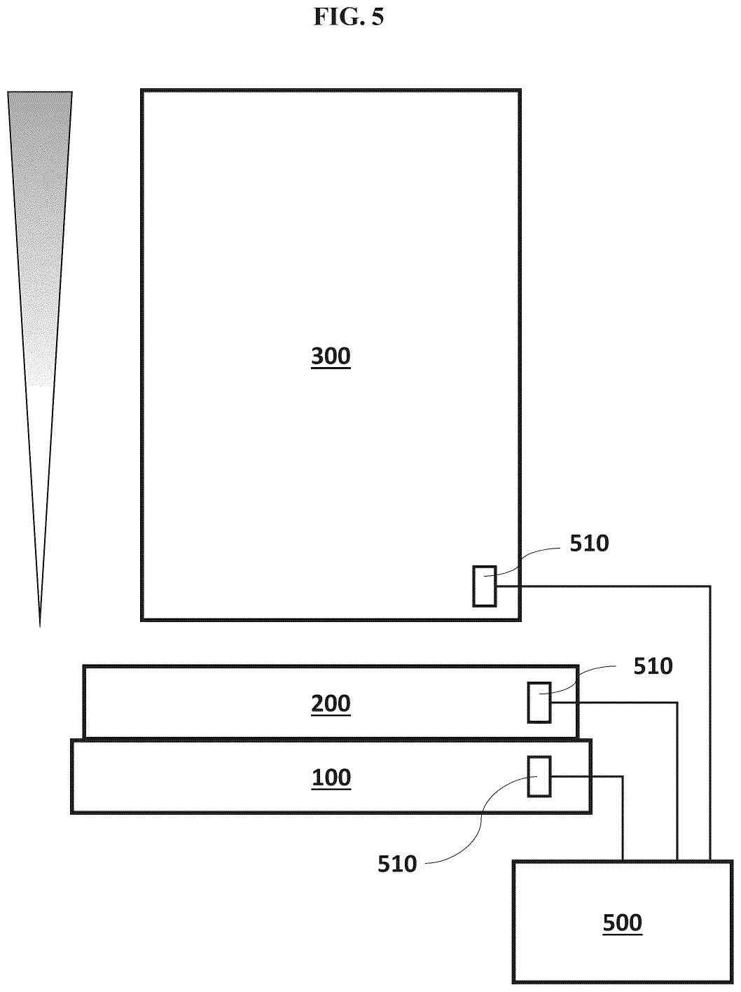

With reference to FIG. 5, in some embodiments, a control system 500 is used to control one or more of a flow rate of the fluid in cooling lines 110 and a temperature of the fluid in cooling lines 110. The control system 500 can be configured to communicate with one or more sensors 510 configured to detect a running temperature of heating element 200. When the temperature of heating element 200 increases to an upper threshold temperature, the flow rate of the fluid in cooling lines 110 can increase and/or the temperature of the fluid in cooling lines 110 can decrease in order to actively cool the heating element. When the temperature of heating element 200 decreases to a lower threshold temperature, the flow rate of the fluid in cooling lines 110 can decrease and/or the temperature of the fluid in cooling lines 110 can increase in order to reduce the function of cooling element 100.

As discussed above, in some embodiments, cooling element 100 is of the same shape or a similar shape as heating element 200. In some embodiments heating element 200 is a heating plate.

In some embodiments, cooling plate 150 comprises an element that is a good conductor of heat. In some embodiments, cooling plate 150 comprises aluminum, stainless steel, nickel, or hastelloy. In some embodiments, cooling lines 110 and clamps 130 comprise stainless steel, aluminum, nickel, or hastelloy. However, any suitable materials may be used for cooling plate 150, cooling lines 110, clamps 130, and any other attachment means used in cooling apparatus 100.

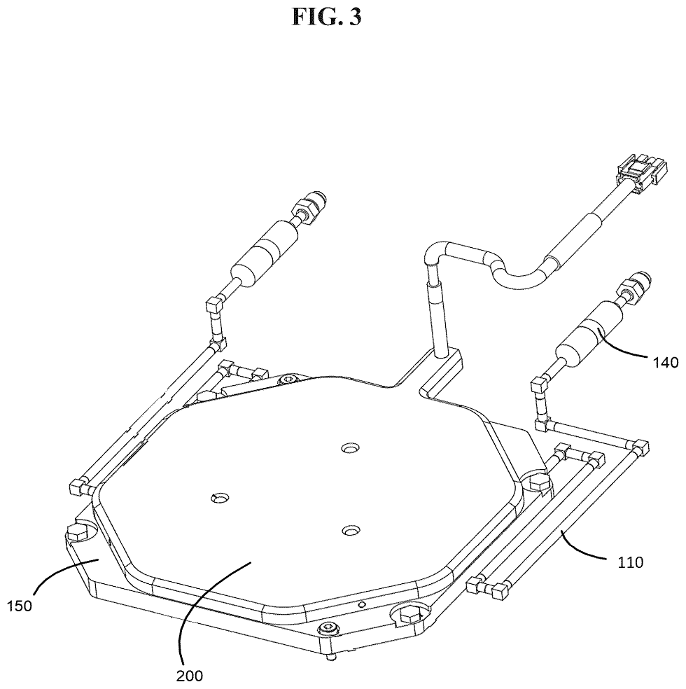

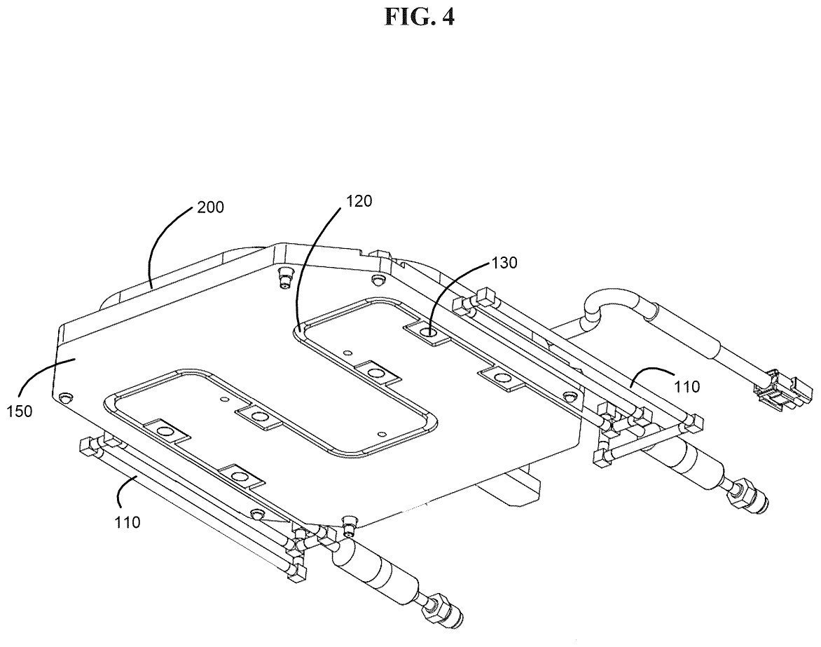

Cooling apparatus 100 may be designed to accommodate any source vessel 300, illustrated in FIG. 5. For example, FIGS. 3 and 4 illustrate a cooling apparatus 100 and a heating element 200 disposed on the top side of cooling apparatus 100, which is configured for use with a different source vessel than that of FIGS. 1 and 2.

With reference again to FIG. 5, a solid source delivery assembly according to an embodiment includes source vessel 300, heating element 200, and cooling apparatus 100. In some embodiments, heating element 200 is disposed at the base of source vessel 300. In other embodiments, heating element 200 may be additionally or alternatively disposed above the source vessel 300. Heating element 200 may be disposed at any location surrounding source vessel 300. In some embodiments, cooling apparatus 100 is in thermal contact with heating element 200. In some embodiments, heating element 200 is a resistive heater, such as a heating plate.

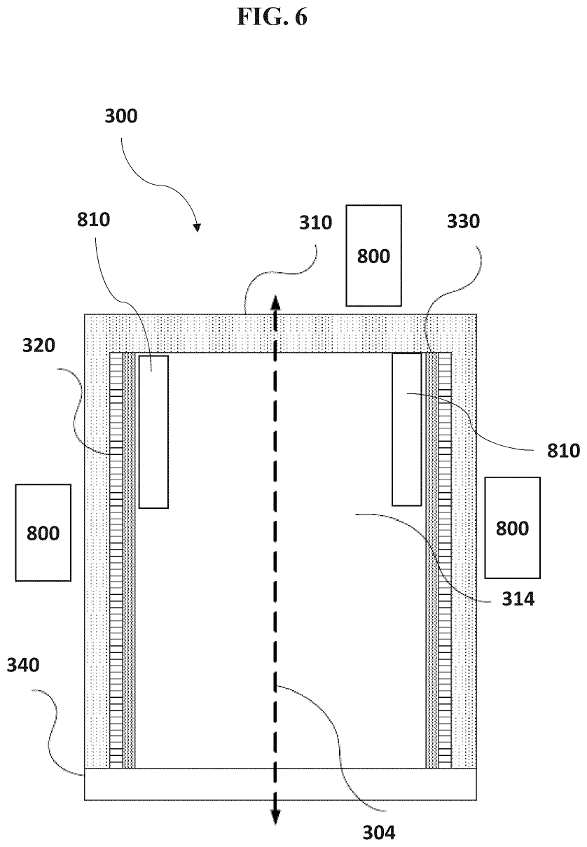

An exemplary source vessel for use with the present invention is shown in greater detail in FIG. 6. In some embodiments, source vessel 300 includes a base 340, a filter frame 320, a filter 330, and a housing 310. Filter 330 can have a porosity configured to restrict a passage (or transfer) of a chemical reactant through the filter 330. Source vessel 300 may define a source vessel axis 304. In some embodiments, base 340 is configured to hold a solid source chemical. Base 340 may comprise a substantially planar surface for holding the chemical reactant, but other shapes and variants are possible. In some embodiments, source vessel 300 defines an interior 314, encompassing the space between the walls of housing 310 and between a ceiling of housing 310 and a floor of base 340. In some embodiments, the interior 314 is configured to contain a chemical reactant such as a solid source chemical.

FIG. 6 should not be viewed as limiting the number of elements source vessel 300 can contain. For example, in addition to heating element 200, the assembly typically also includes one or more separate heaters. In some embodiments, one or more of the separate heaters 800 can be disposed vertically adjacent or vertically proximate to source vessel 300. In some embodiments, the one or more separate heaters are configured to heat source vessel 300 by conduction. In some embodiments, one or more valves many be heated conductively and/or radiantly. In some embodiments, one or more feed throughs 810 for receiving one or more heaters can be included in the walls and/or center (e.g. in interior 314) of source vessel 300 to provide more direct heat to the chemical reactant.

In some embodiments, the precursor source vessel 300 can have a height: diameter aspect ratio in the range of about 1-4. In some embodiments, the source vessel occupies a shape approximating a cylinder, but other shapes are possible. As such, in some embodiments, housing 310 comprises, consists essentially of, or consists of a cylindrical shape. In some embodiments, the mass of the source vessel 300 (unfilled) in various embodiments described herein can range from about 1 kg to about 100 kg, or about 10 kg to about 50 kg. In some embodiments, the mass of the filled source vessel 300 can range from about 10 kg to about 180 kg, or about 35 kg to about 85 kg. Lower masses of vessels can allow for easier transportation, but higher masses can facilitate higher volume reactant and necessitate fewer refills.

Source vessel 300 is configured to operate at an operating temperature. For example, the operating temperature may be determined based on a desired subliming rate of the chemical precursor/reactant. In some embodiments, the operating temperature is in the range of about 20° C.-250° C. The selected operating temperature may depend upon the chemical to be vaporized. For example, the operating temperature may be about 160° C.-240° C., particularly about 170° C.-190° C. for HfCl₄; about 170° C.-250° C., particularly about 180° C.-200° C. for ZrCl₄; about 90° C.-110°° C. for Al₂Cl₃; or about 90° C.-120° C. for Sil₄. The skilled artisan will appreciate other temperatures may be selected for other source chemicals.

Source vessels are typically supplied with gas lines extending from the inlet and outlet, isolation valves on the lines, and fittings on the valves, the fittings being configured to connect to the gas flow lines of a reaction chamber. It is often desirable to provide a number of heaters for heating the various valves and gas flow lines between the source vessel and the reaction chamber, to prevent the source vapor from condensing and depositing on such components. Accordingly, the gas-conveying components between the source vessel and the reaction chamber are sometimes referred to as a “hot zone” in which the temperature is maintained above the vaporization/condensation/sublimation temperature of the reactant.

In some embodiments, the source vessel, e.g. within the housing 310, is set to a target vacuum pressure. In some embodiments, the target vacuum pressure is in the range of about a vacuum pressure to 760 Torr, or about 100 and 2000 Torr. In some embodiments, the target vacuum pressure is between about 3 Torr and 350 Torr. In some embodiments, the target vacuum pressure is between about 50 and 250 Torr. In preferred embodiments, the vacuum pressure is between 5 and 50 Torr. In some embodiments, the vacuum pressure is 25 Torr. The vacuum pressure generates a uniform temperature profile within the source vessel.

As illustrated in FIG. 5, as cooling apparatus 100 continuously draws thermal energy from heating element 200, a heat gradient is formed. The gradient is cooler at the base of source vessel 300, where the precursor source is predisposed, and gradually gets hotter at the ceiling of vessel 300. This controlled temperature gradient prevents or can mitigate hot spots, cold spots, and undesired condensation within the vessel, and can keep the precursor source at a cooler temperature than the surroundings within and exterior to vessel 300, which, in turn, can prevent or mitigate undesired decomposition or degradation of the precursor. In other embodiments, where heating element and cooling apparatus are disposed at other locations surrounding the source vessel, the temperature gradient is cooler at the location of the heating element and cooling apparatus and gradually gets hotter at the opposite end of the vessel.

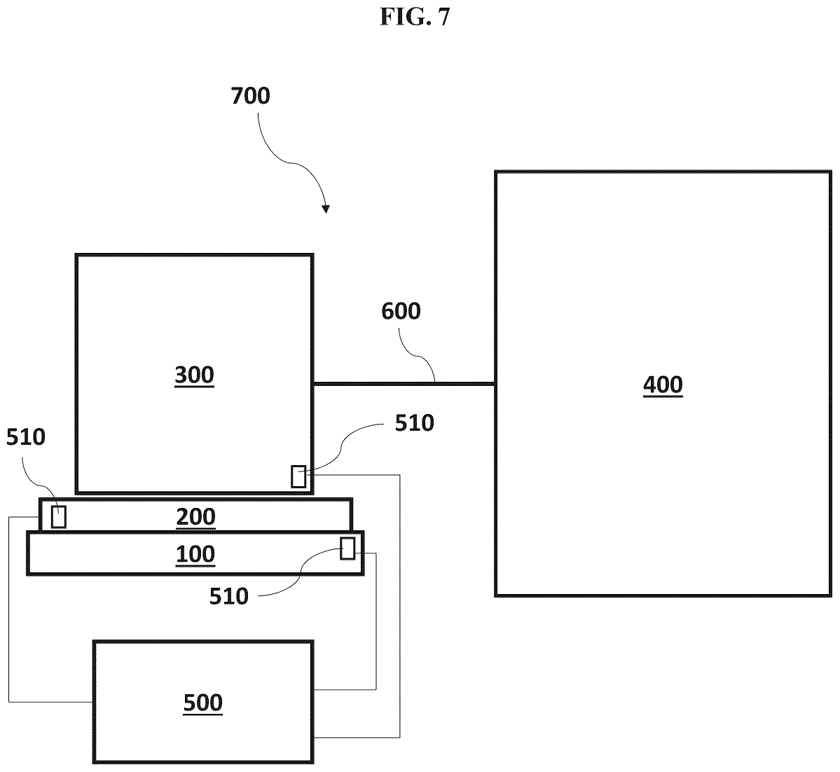

As illustrated in FIG. 7, the assembly may be used in a reactor system 700. The system 700 may comprise a precursor source vessel 300, a heating element 200, and a cooling apparatus 100, as well as a reactor 400. System 700 can also include a controller, such as controller 500 described above. The precursor is fed from the vessel 300 to the reactor 400 through one or more gas lines 600.

In some embodiments, a method is provided for controlling the temperature of an interior of a source vessel, comprising heating the source vessel with a heating element, and cooling the heating element with a cooling apparatus. The heating element can continually provide heat (e.g., not power off) to the interior of the source vessel in order to maintain a desired operating temperature of the source vessel—e.g., a temperature between about 90° C. and about 250° C., or between about 110° C. and about 210° C. Generally, an operating temperature is greater than the sublimation temperature of the precursor and less than the decomposition temperature of the precursor. The cooling apparatus, as described above, can be used to actively cool the heating element in order to maintain the desired operating temperature of the heating element and/or vessel and/or precursor within the vessel and to provide a desired temperature gradient within precursor source vessel 300.

In some embodiments, a method is provided for rapidly reducing the temperature of the interior of the precursor source vessel by powering off the heating element, and cooling the heating element using the cooling apparatus.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In this disclosure, “continuously” can refer to one or more of without breaking a vacuum, without interruption as a timeline, without any material intervening step, without changing treatment conditions, immediately thereafter, as a next step, or without an intervening discrete physical or chemical structure between two structures other than the two structures in some embodiments.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

What is claimed is:

1. A method of controlling the temperature of an interior of a precursor source vessel, the method comprising heating the precursor source vessel using a heating element, and cooling the heating element using a cooling apparatus.

2. The method of claim 1, wherein the interior is heated to a desired temperature that is greater than the sublimation temperature of a precursor and less than the decomposition temperature of the precursor.

3. The method of claim 1, wherein the desired temperature is between about 90° C. and 250° C., or about 110° C. and about 210° C.

4. The method of claim 1, wherein the heating element continually provides heat during a substrate process to maintain the desired temperature.

5. The method of claim 1, wherein a pressure within the precursor source vessel is between about a vacuum pressure and about 760 Torr.

6. The method of claim 5, wherein the pressure within the precursor source vessel is between about 5 and about 50 Torr.

7. The method of claim 1, wherein the cooling apparatus comprises a top side and a bottom side, wherein the top side thermally contacts the heating element, and wherein one or more cooling lines are attached to a perimeter of the bottom side of the cooling apparatus.

8. The method of claim 7, wherein the cooling lines are configured to hold water, and wherein at least one of a flow rate of the water and a temperature of the water can be used to manipulate the cooling function of the cooling apparatus.

9. The method of claim 1, wherein a temperature gradient forms within the interior from a first temperature at a bottom end of the precursor source vessel and a second temperature near a top end of the precursor source vessel,
wherein the first temperature is less than the second temperature.

10. The method of claim 1, wherein the heating element is turned off and the cooling apparatus draws residual heat from the heating element, thereby rapidly reducing the temperature of the interior of the precursor source vessel.

11. The method of claim 1, wherein the heating element is external of the precursor source vessel.

12. The method of claim 11, where in the cooling apparatus is external of the precursor source vessel.

13. The method of claim 12, wherein a bottom side of the heating element is disposed on a top side of the cooling apparatus.

14. The method of claim 13, further comprising removing, by the cooling apparatus, heat from the heating element.
